(19) United States
(12) Patent Application Publication
(10) Pub. No.: US 2007/0228493 A1
(43) Pub. Date: Oct. 4, 2007

(54) Plasma display panel

(76) Inventors: Se-Jong Kim, Suwon-si (KR); Hyun Soh, Suwon-si (KR); Yun-Hee Kim, Suwon-si (KR); Hyun Kim, Suwon-si (KR); Kyoung-Doo Kang, Suwon-si (KR)

Correspondence Address: Robert E. Bushnell;Suite 300, 1522 K Street, N.W., Washington, DC, 20005-1202, US

(21) Appl. No.: 11/730,132

(22) Filed: Mar. 29, 2007

(30) Foreign Application Priority Data
Mar. 30, 2006 (KR) 10-2006-0029110

(51) Int. Cl. H01L 29/76

(52) U.S. Cl. 257/401

(57) ABSTRACT

A design for a plasma display panel that results in improved visible ray transmissivity. The plasma display panel includes a substrate, a plurality of discharge electrode pairs arranged on the substrate and spaced apart from each other, a dielectric layer covering the plurality of discharge electrode pairs, the dielectric layer including a plurality of grooves are arranged thereon and a protective layer including a first protective layer arranged on side surfaces of the plurality of grooves, a second protective layer arranged on portions of the dielectric layer outside the grooves, and a third protective layer arranged on bottom surfaces of the plurality of grooves, a thickness of the first protective layer being less than a thickness of each of the second and the third protective layers.

### CLAIM OF PRIORITY

This application makes reference to, incorporates the same herein, and claims all benefits accruing under 35 U.S.C.§119 from an application for PLASMA DISPLAY PANEL earlier filed in the Korean Intellectual Property Office on 30 Mar. 2006 and there duly assigned Serial No. 10-2006-0029110.

### BACKGROUND OF THE INVENTION

1. Field of the Invention

The present invention relates to a novel design for a plasma display panel (PDP) in which visible ray transmissivity is improved.

2. Description of the Related Art

Recently, plasma display panels (PDP) have come into the spotlight for replacing conventional cathode ray tube (CRT) display apparatuses. PDPs are flat display devices in which a discharge gas is sealed between two substrates in which a plurality of electrodes are formed, and then a discharge voltage is applied, and a phosphor layer formed in a predetermined pattern is excited by ultraviolet rays generated by a discharge process and desired images are obtained.

A 3-electrode surface discharge AC type PDP includes an upper plate and a lower plate combined with the upper plate that are parallel to each other. Discharge electrode pairs in which an X electrode and a Y electrode form a pair, are disposed on a front substrate of the upper plate, and address electrodes are disposed on a rear substrate of the lower plate opposing the front substrate to cross the X electrode and the Y electrode. Each of the Y electrode and the X electrode includes a transparent electrode and a bus electrode. A front dielectric layer and a rear dielectric layer are formed on the front substrate and the rear substrate, respectively, to bury discharge electrode pairs and address electrodes. A protective layer, usually made out of magnesium oxide (MgO), is formed on the front dielectric layer. Barrier ribs, for keeping a discharge distance and for preventing electrical and optical cross-talk between discharge cells, are formed on a front surface of the rear dielectric layer. A phosphor layer is applied on both side surfaces of the barrier ribs and on a portion of the rear dielectric layer in which the barrier ribs are not formed. Visible rays generated in the phosphor layer must pass through the protective layer, the front dielectric layer and the front substrate to be viewed by a viewer. Requiring visible light to go through all these materials attenuates the image, especially when these materials are thick. As a result, the PDP having this structure has a low visible ray transmissivity. Therefore, what is needed is a design for a PDP where visible ray transmissivity is improved.

### SUMMARY OF THE INVENTION

The present invention provides a design for a plasma display panel (PDP) in which visible ray transmissivity is improved.

According to an aspect of the present invention, there is provided a plasma display panel including a substrate, a plurality of discharge electrode pairs arranged on the substrate and spaced apart from each other, a dielectric layer covering the plurality of discharge electrode pairs, the dielectric layer including a plurality of grooves are arranged thereon and a protective layer including a first protective layer arranged on side surfaces of the plurality of grooves, a second protective layer arranged on portions of the dielectric layer outside the grooves, and a third protective layer arranged on bottom surfaces of the plurality of grooves, a thickness of the first protective layer being less than a thickness of each of the second and the third protective layers.

Portions of the dielectric layer corresponding to side surfaces of the plurality of grooves can form an inclined surface with respect to the substrate, and an angle between the inclined surface and the substrate being in a range about from 70 to 90 degrees. The second protective layer can have a thickness greater than that of the third protective layer. Each of the plurality of grooves can extend completely through the dielectric layer to expose corresponding portions of the substrate. Each of the plurality of grooves may not extend entirely through the dielectric layer. Each of the first protective layer, the second protective layer, and the third protective layer can include a same material. Each of the first protective layer, the second protective layer, and the third protective layer can include magnesium oxide (MgO). Each of the discharge electrodes pairs can include at least one of the plurality of grooves therebetween.

According to another aspect of the present invention, there is provided a plasma display panel including a rear substrate, a front substrate opposing the rear substrate, a plurality of barrier ribs arranged between the front substrate and the rear substrate and partitioning a plurality of discharge cells, a plurality of discharge electrode pairs arranged on the front substrate and spaced apart from each other, a dielectric layer covering the plurality of discharge electrode pairs, the dielectric layer including a plurality of grooves are arranged thereon, a protective layer including a first protective layer arranged on side surfaces of the plurality of grooves, a second protective layer arranged on portions of the dielectric layer outside the grooves, and a third protective layer arranged on bottom surfaces of the plurality of grooves, a plurality of address electrodes extending across the discharge electrode pairs and arranged on the rear substrate, a plurality of phosphor layers arranged within the plurality of discharge cells and a discharge gas arranged within the discharge cells, wherein a thickness of the first protective layer being less than a thickness of each of the second and the third protective layers.

Portions of the dielectric layer corresponding to side surfaces of the plurality of grooves can form an inclined surface with respect to the front substrate, and an angle between the inclined surface and the substrate being in a range about from 70 to 90 degrees. The second protective layer can have a thickness greater than that of the third protective layer. Each of the plurality of grooves can extend completely through the dielectric layer to expose corresponding portions of the front substrate. Each of the plurality of grooves may not extend entirely through the dielectric layer. Each of the first protective layer, the second protective layer, and the third protective layer can include a same material. Each of the first protective layer, the second protective layer, and the third protective layer can include magnesium oxide (MgO). Each of the discharge electrodes pairs can include at least one of the plurality of grooves therebetween.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 illustrates a vertical cross-sectional view of a structure of a plasma display panel (PDP);

FIG. 2 illustrates an exploded perspective view of a PDP according to an embodiment of the present invention;

FIG. 3 illustrates a cross-sectional view taken along line III-III of FIG. 2;

FIG. 4 illustrates an enlarged view of portion A of FIG. 3;

FIG. 5 illustrates an arrangement view illustrating positions of discharge cells, electrodes, and grooves illustrated in FIG. 2;

FIG. 6 illustrates an arrangement view illustrating discharge electrodes having different shapes from those of FIG. 2 as a first modification example of FIG. 2;

FIG. 7 illustrates an arrangement view illustrating grooves having different depths from those of FIG. 2 as a second modification example of FIG. 2; and

FIGS. 8A and 8B illustrate schematic cross-sectional views illustrating states where protective layers are deposited when angles between an inclined surface and a front substrate are different.

### DETAILED DESCRIPTION OF THE INVENTION

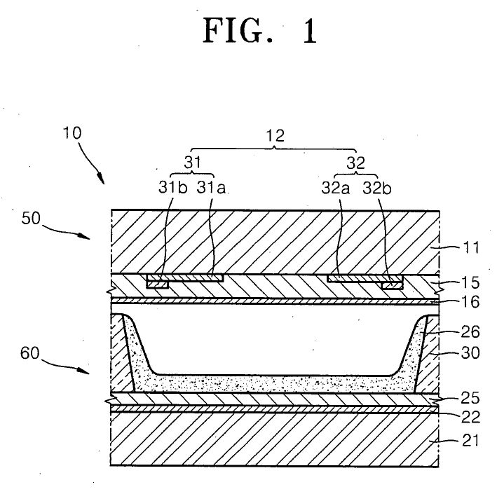

Turning now to the figures, FIG. 1 illustrates a view of a 3-electrode surface discharge AC type PDP 10. Referring to FIG. 1, the PDP 10 includes an upper plate 50 and a lower plate 60 combined with the upper plate 50 and parallel to each other. Discharge electrode pairs 12, in which an X electrode 31 and a Y electrode 32 form a pair, are disposed on a front substrate 11 of the upper plate 50, and address electrodes 22 are disposed on a rear substrate 21 of the lower plate 60 opposing the front substrate 11 to cross the X electrode 31 and the Y electrode 32. Each of the Y electrode 32 and the X electrode 31 includes transparent electrodes 32a and 31a and bus electrodes 32b and 31b. A front dielectric layer 15 and a rear dielectric layer 25 are formed on the front substrate 11 and the rear substrate 21, respectively, to bury discharge electrode pairs 12 and address electrodes 22. A protective layer 16, usually made out of magnesium oxide (MgO), is formed on the front dielectric layer 15, and barrier ribs 30, for keeping a discharge distance and for preventing electrical and optical cross-talk between discharge cells, are formed on a front surface of the rear dielectric layer 25. A phosphor layer 26 is applied on both side surfaces of the barrier ribs 30 and on portions of the rear dielectric layer 25 in which the barrier ribs 30 are not formed. Because visible light produced in the phosphor layer 26 must travel through the protective layer 16, the front dielectric layer 15 and the front substrate 11 to be viewed by a viewer, this visible light is attenuated significantly before it is viewed. The amount of attenuation can be large, especially when these materials are thick. As a result, the PDP 10 of FIG. 1 has a low visible ray transmissivity.

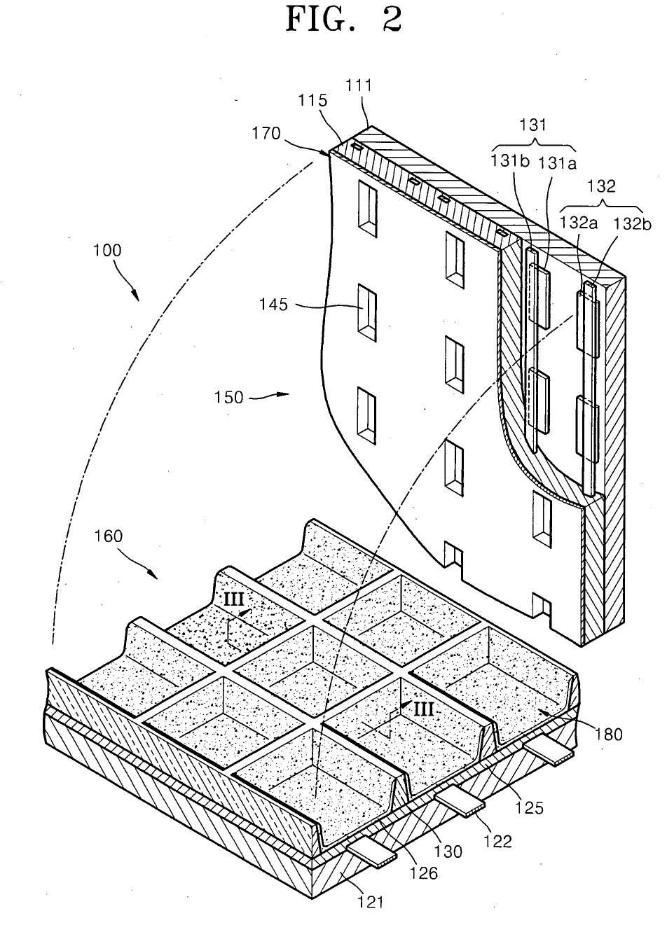

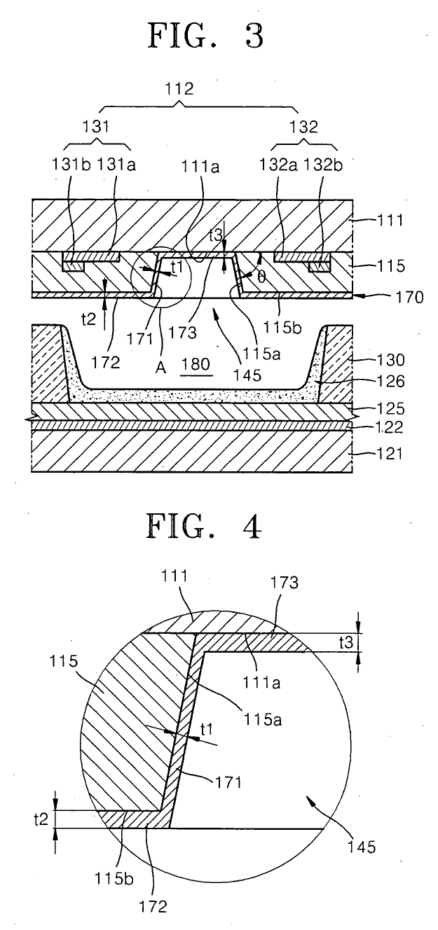

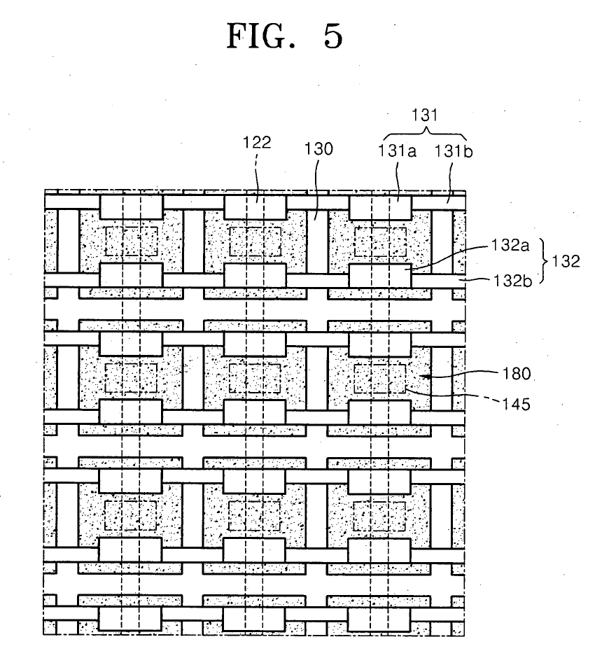

Turning now to FIGS. 2 through 5, FIGS. 2 through 5 illustrate a plasma display panel (PDP) 100 according to an embodiment of the present invention. Specifically, FIG. 2 is an exploded perspective view of PDP 100, FIG. 3 is a cross-sectional view taken along line III-III of FIG. 2, FIG. 4 is an enlarged view of portion A of FIG. 3 and FIG. 5 is an arrangement view illustrating positions of discharge cells 180, electrodes 131, 132, and 122, and grooves 145 illustrated in FIG. 2. Hereinafter, like reference numerals denote like elements.

As illustrated in FIGS. 2 and 3, the PDP 100 includes an upper plate 150 and a lower plate 160 combined with the upper plate 150 and parallel thereto. The upper plate 150 includes a front substrate 111, a front dielectric layer 115, discharge electrode pairs 112, and a protective layer 170. The lower plate 160 includes a rear substrate 121, address electrodes 122, a rear dielectric layer 125, barrier ribs 130, and phosphor layers 126.

The front substrate 111 and the rear substrate 121 are spaced apart from each other by a predetermined gap and define discharge spaces in which discharges occur between the front substrate 111 and the rear substrate 121. The front substrate 111 and the rear substrate 121 can be made out of glass having excellent visible ray transmissivity. However, for improvement of a bright room contrast, the front substrate 111 and/or the rear substrate 121 can be colored.

Barrier ribs 130 are disposed between the front substrate 111 and the rear substrate 121. More specifically, the barrier ribs 130 are disposed on the rear dielectric layer 125. The barrier ribs 130 partition the space between the front and rear substrates into a plurality of discharge cells 180 and prevent optical/electrical cross-talk between the discharge cells 180. In FIG. 2, the barrier ribs 130 form discharge cells 180 in a matrix configuration with each discharge cell having a rectangular cross-section, however the present invention is not limited to this. Alternatively, the barrier ribs 130 can instead have a cross-section of a polygonal shape such as a triangular or pentagonal shape, a circular shape or an elliptical shape, and can also be formed in an opened manner such as in the form of stripes. Alternatively, the barrier ribs 130 can partition the discharge cells 180 in a waffle or delta arrangement.

The discharge electrode pairs 112 are disposed on the front substrate 111 that opposes the rear substrate 121. The discharge electrode pairs 112 are arranged on the front substrate 111 to be parallel to one another and separated from each other by a predetermined gap. Each of the discharge electrode pairs 112 includes an X electrode 131 and a Y electrode 132. In the present embodiment, the discharge electrode pairs 112 are directly disposed on the front substrate 111, but the arrangement positions of the discharge electrode pairs 112 are not limited to this. Alternatively, the discharge electrode pairs 112 can be spaced apart from one another by a predetermined gap in a direction from the front substrate 111 toward the rear substrate 121.

Each of the X electrode 131 and the Y electrode 132 includes transparent electrodes 131a and 132a and bus electrodes 131b and 132b. The transparent electrodes 131a and 132a can be made out of a transparent material, such as indium tin oxide (ITO). However, transparent electrodes formed of ITO have a large voltage drop in a lengthwise direction. Thus, a large amount of driving power is consumed and a response speed is low. To solve this problem, the bus electrodes 131b and 132b, formed of a highly conductive metallic material and having a narrow width, are formed on the transparent electrodes 131a and 132b. The bus electrodes can be formed to have a single layer structure using metal such as Ag, Al or Cu or can also be formed to have a multi-layer structure. The transparent electrodes and the bus electrodes are formed using photo-etching or photolithography.

In the shape and arrangement of the X electrode 131 and the Y electrode 132, the bus electrodes 131b and 132b are spaced apart from each other by a predetermined gap and are parallel to each other in a unit discharge cell 180 and extend across the discharge cells 180 disposed in one direction. As described above, the transparent electrodes 131a and 132a are electrically connected to the respective bus electrodes 131b and 132b. The transparent electrodes 131a and 132a are discontinuously disposed in each of the discharge cells 180. One side of each of the transparent electrodes 131a and 132a is connected the bus electrodes 131b and 132b respectively, and the other side of each of the transparent electrodes 131a and 132a is oriented toward a central portion of ones of the discharge cells 180.

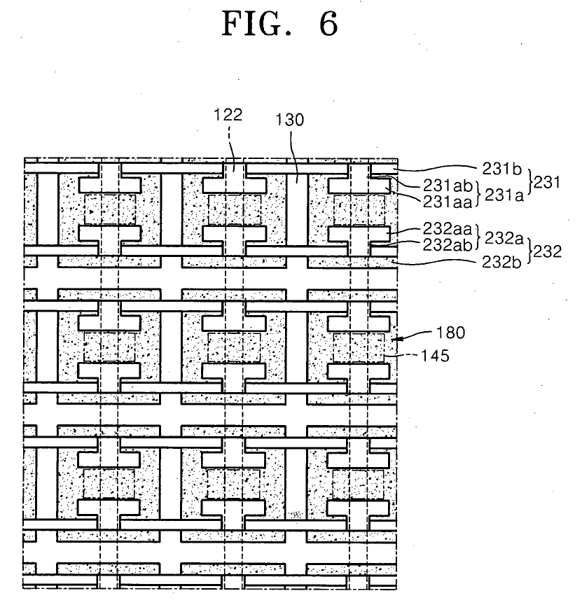

Despite the above design considerations, the transparent electrodes can be formed to have other various shapes. For example, in FIG. 6, a hammer-shaped X electrode 231 and a hammer-shaped Y electrode 232 are shown. Each of the X electrode 231 and the Y electrode 232 includes a plurality of transparent electrodes 231a and 232a and bus electrodes 231b and 232b. Each transparent electrode 231a of the X electrode 231 includes a discharge portion 231aa disposed to be spaced apart from the bus electrode 231b of the X electrode 231 and located at an inside portion of a discharge cell 180, and a connection portion 231ab for connecting the discharge portion 231aa to the bus electrode 231b of the X electrode 231. In addition, each transparent electrode 232a of the Y electrode 232 includes a discharge portion 232aa located at a distance from the bus electrode 232b of the Y electrode 232 and located at an inside portion of a discharge cell 180, and a connection portion 232ab for connecting the discharge portion 232aa to the bus electrode 232b of the Y electrode 232. The discharge portions 231aa and 232aa of the X electrode 231 and the Y electrode 232 have a short gap therebetween and thus have an advantage of reducing a discharge voltage. In addition, since the transparent electrodes are designed to have a structure that minimizes the area that the transparent electrodes cover, they have an advantage of improving visible ray transmissivity.

Referring to FIGS. 2 and 3, a front dielectric layer 115 is formed on the front substrate 111 to bury the discharge electrode pairs 112. The front dielectric layer 115 prevents the X electrode 131 and the Y electrode 132 from being electrically shorted while simultaneously preventing charged particles or electrons from directly colliding with the X electrode 131 or the Y electrode 132, thus preventing the X electrode 131 and the Y electrode 132 from being damaged. In addition, the front dielectric layer 115 performs the function of inducing charges. The front dielectric layer 115 can be made out of PbO, B₂O₃ or SiO₂.

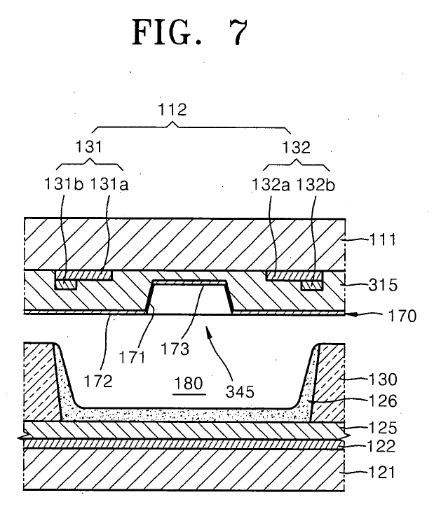

Grooves 145 are formed in the front dielectric layer 115 at a location between an X electrode 131 and a Y electrode 132 that forms a pair. The grooves 145 are formed so that portions 111a of the front substrate 111 are exposed by the grooves 145. However, the depth of the grooves 145 can be determined in various ways. In FIG. 7 for example, grooves 345 formed in a front dielectric layer 315 are shown. Referring to FIG. 7, the grooves 345 are not formed so that the front substrate 111 is exposed by the grooves 345, but are instead formed only to a predetermined depth within the front dielectric layer 315.

Referring to FIGS. 2 and 5, there is a one-to-one correspondence between grooves 145 and discharge cells 180. Since the thickness of the front dielectric layer 115 is reduced by the grooves 145, visible ray transmissivity in a forward direction is improved. In the present embodiment, the grooves 145 are formed to have a substantially quadrangular cross-section, but the present invention is not limited to this and can be formed to have other various shapes. The surface of the front dielectric layer 115 is divided into first front dielectric layer portions 115a forming side surfaces of the grooves 145, and second front dielectric layer portions 115b which are located outside the grooves 145, are substantially flat with respect to the front substrate 111 and exclude the first front dielectric layer portions 115a.

A protective layer 170 is formed to cover the front dielectric layer 115. The protective layer 170 includes first protective layer portions 171 formed on the first front dielectric layer portions 115a, second protective layer portions 172 formed on the second front dielectric layer portions 115b, and third protective layer portions 173 formed to correspond bottom surfaces of the grooves 145. In particular, the third protective layer portions 173 are formed on the front substrate portions 111a exposed by the grooves 145.

Referring to FIG. 3, the first front dielectric layer portions 115a form an inclined surface 190 with respect to the front substrate 111. The inclined surface 190 forms a predetermined angle θ with respect to the front substrate 111. When the angle θ is small, the amount of visible rays generated in the discharge cells 180 that reaches the inclined surface 190 increases. However, since visible rays reaching the inclined surface 190 are reflected, scattered and refracted by the inclined surface 190, visible ray transmissivity of the inclined surface 190 is very low. Thus, in order to increase visible ray transmissivity, the projection area of the inclined surface 190 onto the front substrate 111 must be reduced. In consideration of facility of a method of forming the grooves 145 as well as a decrease in the projection area, the angle θ formed by the inclined surface 190 and the front substrate 111 can be about from 70 to 90 degrees.

In addition, the protective layer 116 is made out of magnesium oxide (MgO), which has a high secondary electron emission coefficient and a high visible ray transmissivity. Although the protective layer 116 is formed of material having high visible ray transmissivity, it is difficult for the protective layer 116 to have 100% transmissivity. Thus, the first protective layer portions 171 formed on the inclined surface 190 cause visible ray transmissivity at the inclined surface 190 to further deteriorate. Thus, in order to improve visible ray transmissivity, the thickness t1 of the first protective layer portions 171 is made smaller than each of the thickness t2 of the second protective layer portions 172 and the thickness t3 of the third protective layer portions 173. In this case, the second protective layer portions 172 can have substantially the same thickness as that of the third protective layer portions 173, but can also have a different thickness from that of the third protective layer portions 173.

In the PDP 100, a portion where the amount of excitation species and the amount of ions are large is a discharge gap portion between the X electrode 131 and the Y electrode 132. In particular, since the grooves 145 are formed between the X electrode 131 and the Y electrode 132, there is a characteristic that an electric field is more concentrated in the vicinity of the grooves 145. Thus, in the grooves 145, the amount of the excitation species and ions greatly increase and the electric field is concentrated so that discharge concentration occurs in the grooves 145. A discharge voltage is reduced therefrom. In addition, the protective layer 170 prevents charged particles and electrons from colliding with the front dielectric layer 115 and preventing the front dielectric layer 115 from being damaged and makes a plasma discharge smooth by emitting a large amount of secondary electrons during a discharge.

As described above, since a discharge is concentrated in the vicinity of the grooves 145, a discharge fires in the grooves 145. The fired discharge is diffused to edges of the discharge cells 180. However, when the discharge is excessively concentrated at the grooves 145, discharge diffusion does not occur smoothly. Considering that luminous efficiency generally increases as a discharge path is more lengthened, the degree of discharge diffusion has a close relationship with luminous efficiency. Thus, the structure of the PDP which enables discharge diffusion to be smoothly performed is required.

In the present embodiment, since the thickness t1 of the first protective layer portions 171 is smaller than the thickness t2 of the second protective layer portions 172, the emission amount of secondary electrons outside the grooves 145 can be increased. Thus, a discharge occurs briskly outside the grooves 145 and a discharge is smoothly diffused so that luminous efficiency is improved.

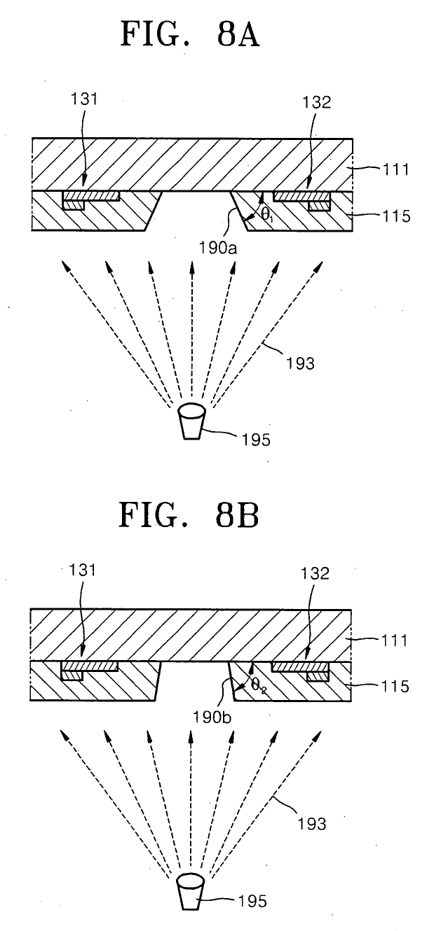

The protective layer 170 can be formed via deposition. In particular, in order to adjust the thicknesses of the first protective layer portions 171, the second protective layer portions 172, and the third protective layer portions 173, the angle θ of the inclined surface 190 with respect to the front substrate 111 is controlled, which will now be described in detail with reference to FIGS. 8A and 8B.

After a dielectric paste is printed on the front substrate 111, the grooves 145 are formed using etching processing, sand blasting processing or photosensitive sheet processing. After that, the protective layer 170 is formed on the front dielectric layer 111 using deposition.

In FIGS. 8A and 8B, the angle of a first inclined surface 190a and the angle of a second inclined surface 190b are a first angle θ₁ and a second angle θ₂, respectively. Here, the first angle θ₁ is smaller than the second angle θ₂. Referring to FIGS. 8A and 8B, assuming the same deposition conditions, the amount of the deposition material 193 generated by the deposition source 195 that reaches the second inclined surface 190b is smaller than the amount of the deposition material 193 generated in the deposition source 195 that reaches the first inclined surface 190a. Thus, the thickness of a protective layer of the first inclined surface 190a is larger than the thickness of a protective layer of the second inclined surface 190b. In order to more precisely control the thickness of the protective layer, a deposition mask can be further disposed between the front dielectric layer 115 and the deposition source 195.

Address electrodes 122 are disposed on the rear substrate 121 that opposes the front substrate 111. The address electrodes 122 extend across the discharge cells 180 to cross the X electrodes 131 and the Y electrodes 132. The address electrodes 122 cause an address discharge that facilitates a sustain discharge between the X electrode 131 and the Y electrode 132. More specifically, the address discharge serves to reduce a voltage required for the sustain discharge while selecting which discharge cells 180 will undergo a sustain discharge. The address discharge occurs between the Y electrode 132 and the address electrode 122.

A rear dielectric layer 125 is formed on the rear substrate 121 to bury the address electrodes 122. The rear dielectric layer 125 is formed of dielectric material that prevents charged particles or electrons from colliding with the address electrodes 122, thus preventing the address electrodes 122 from being damaged. Rear dielectric layer 125 also serves to induce charges, and is made out of PbO, B₂O₃ or SiO₂.

Red, green, and blue light-emitting phosphor layers 126 are disposed on both side surfaces of the barrier ribs 130 formed on the rear dielectric layer 125 and on the front surface of the rear dielectric layer 125 at locations where the barrier ribs 130 are not formed. The phosphor layers 126 include components which produce visible rays upon being excited by ultraviolet rays. The phosphor layers 126 formed in red light-emitting discharge cells include phosphor such as Y(V,P)O₄:Eu, the phosphor layers 126 formed in green light-emitting discharge cells include phosphor such as Zn₂SiO₄:Mn, YBO₃:Tb, and the phosphor layers 126 formed in blue light-emitting discharge cells include phosphor such as BAM:Eu.

In addition, a discharge gas, in which Ne and Xe are mixed, fills the discharge cells 180. The front substrate 111 and the rear substrate 121 are sealed together by a sealing member such as frit glass formed on edges of the front substrate 111 and the rear substrate 121 in the state where the discharge gas is filled within the discharge cells 180, and are combined with each other.

The operation of the PDP 100 having the above structure according to the present invention will now be described. A plasma discharge that occurs within the PDP 100 is largely classified into an address discharge and a sustain discharge. The address discharge occurs when an address discharge voltage is applied between the address electrode 122 and the Y electrode 132, and the discharge cells 180 in which a sustain discharge will occur as the result of the address discharge, are selected. After the address discharge in selected discharge cells, a sustain voltage is applied between the X electrode 131 and the Y electrode 132 so that the sustain discharge occurs between the X electrode 131 and the Y electrode 132 in the selected discharge cells.

When the energy level of the excited discharge gas during the sustain discharge is reduced, UV rays are emitted. The UV rays excite the phosphor layer 126 applied within the discharge cells 180. When the energy level of the excited phosphor layer 126 is reduced, visible rays are emitted, and the visible rays are then transmitted through the front dielectric layer 115 and the front substrate 111 so that an image can be perceived by a viewer. Because of the presence of grooves in the front dielectric layer 115, the visible rays produced in the discharge cells pass through less front dielectric material than previously, resulting in less attenuation. As a result, in the PDP according to the present invention, visible ray transmissivity is increased.

While the present invention has been particularly shown and described with reference to exemplary embodiments thereof, it will be understood by those of ordinary skill in the art that various changes in form and details can be made therein without departing from the spirit and scope of the present invention as defined by the following claims.

What is claimed is:

1. A plasma display panel (PDP), comprising:
a substrate;
a plurality of discharge electrode pairs arranged on the substrate and spaced apart from each other;
a dielectric layer covering the plurality of discharge electrode pairs, the dielectric layer including a plurality of grooves are arranged thereon; and
a protective layer including a first protective layer arranged on side surfaces of the plurality of grooves, a second protective layer arranged on portions of the dielectric layer outside the grooves, and a third protective layer arranged on bottom surfaces of the plurality of grooves, a thickness of the first protective layer being less than a thickness of each of the second and the third protective layers.

2. The PDP of claim 1, wherein portions of the dielectric layer corresponding to side surfaces of the plurality of grooves form an inclined surface with respect to the substrate, and an angle between the inclined surface and the substrate being in a range about from 70 to 90 degrees.

3. The PDP of claim 1, wherein the second protective layer has a thickness greater than that of the third protective layer.

4. The PDP of claim 1, wherein each of the plurality of grooves extend completely through the dielectric layer to expose corresponding portions of the substrate.

5. The PDP of claim 1, wherein each of the plurality of grooves do not extend entirely through the dielectric layer.

6. The PDP of claim 1, wherein each of the first protective layer, the second protective layer, and the third protective layer comprise a same material.

7. The PDP of claim 6, wherein each of the first protective layer, the second protective layer, and the third protective layer comprise magnesium oxide (MgO).

8. The PDP of claim 1, wherein each of the discharge electrodes pairs includes at least one of the plurality of grooves therebetween.

9. A plasma display panel (PDP), comprising:
a rear substrate;
a front substrate opposing the rear substrate;
a plurality of barrier ribs arranged between the front substrate and the rear substrate and partitioning a plurality of discharge cells;
a plurality of discharge electrode pairs arranged on the front substrate and spaced apart from each other;
a dielectric layer covering the plurality of discharge electrode pairs, the dielectric layer including a plurality of grooves are arranged thereon;
a protective layer including a first protective layer arranged on side surfaces of the plurality of grooves, a second protective layer arranged on portions of the dielectric layer outside the grooves, and a third protective layer arranged on bottom surfaces of the plurality of grooves;
a plurality of address electrodes extending across the discharge electrode pairs and arranged on the rear substrate;
a plurality of phosphor layers arranged within the plurality of discharge cells; and
a discharge gas arranged within the discharge cells, wherein a thickness of the first protective layer being less than a thickness of each of the second and the third protective layers.

10. The PDP of claim 9, wherein portions of the dielectric layer corresponding to side surfaces of the plurality of grooves form an inclined surface with respect to the front substrate, and an angle between the inclined surface and the front substrate being in a range about from 70 to 90 degrees.

11. The PDP of claim 9, wherein the second protective layer has a thickness greater than that of the third protective layer.

12. The PDP of claim 9, wherein each of the plurality of grooves extend completely through the dielectric layer to expose corresponding portions of the front substrate.

13. The PDP of claim 9, wherein each of the plurality of grooves do not extend entirely through the dielectric layer.

14. The PDP of claim 9, wherein each of the first protective layer, the second protective layer, and the third protective layer comprise a same material.

15. The PDP of claim 14, wherein each of the first protective layer, the second protective layer, and the third protective layer comprise magnesium oxide (MgO).

16. The PDP of claim 9, wherein each of the discharge electrodes pairs includes at least one of the plurality of grooves therebetween.
